(19) United States
(12) Patent Application Publication
(10) Pub. No.: US 2025/0015001 A1
(43) Pub. Date: Jan. 9, 2025

(54) ELECTRONIC COMPONENT AND CIRCUIT DEVICE

(71) Applicant: Murata Manufacturing Co., Ltd., Nagaokakyo-shi (JP)

(72) Inventor: Shota ANDO, Nagaokakyo-shi (JP)

(21) Appl. No.: 18/891,564

(22) Filed: Sep. 20, 2024

Related U.S. Application Data
(63) Continuation of application No. PCT/JP2023/007305, filed on Feb. 28, 2023.

(30) Foreign Application Priority Data
Mar. 23, 2022 (JP) 2022-046259

(51) Int. Cl. H01L 23/532; H01L 23/522

(52) U.S. Cl. CPC H01L 23/53295; H01L 23/5223; H01L 23/5227

(57) ABSTRACT

An electronic component including: a semiconductor substrate; an insulator layer on a first surface of the semiconductor substrate; a plurality of conductor layers on and/or in the insulator layer; a dielectric layer on the first surface of the semiconductor substrate; a lower surface electrode on a second surface of the semiconductor substrate, wherein: at least a first conductor layer of the plurality of conductor layers is a wiring pattern, at least a second conductor layer of the plurality of conductor layers is a plate electrode paired with the semiconductor substrate or the lower surface electrode across the dielectric layer, and the semiconductor substrate has a first region that includes the dielectric layer and the plate electrode and a second region other than the first region; and a conductor portion with higher conductivity than the semiconductor substrate in the first region at a higher ratio than in the second region.

### CROSS REFERENCE TO RELATED APPLICATIONS

The present application is a continuation of International application No. PCT/JP2023/007305, filed Feb. 28, 2023, which claims priority to Japanese Patent Application No. 2022-046259, filed Mar. 23, 2022, the entire contents of each of which are incorporated herein by reference.

### TECHNICAL FIELD

The present disclosure relates to an electronic component including a semiconductor substrate and configured by providing a capacitor, an inductor, and the like, in the semiconductor substrate and a circuit device.

### BACKGROUND ART

Patent Literature 1 discloses a high-frequency integrated circuit device in which a passive device such as an inductor or a capacitor is provided at insulator layers stacked on a semiconductor substrate. All capacitors with which this high frequency integrated circuit device is provided are capacitors of MIM (metal-insulator-metal) structure and those electrodes are placed on a stacked side surface of the insulator layers to the semiconductor substrate.

Patent Literature 2 discloses a semiconductor device provided with a capacitor configured by stacking a dielectric layer and an electrode layer on a semiconductor substrate. One electrode of the capacitor is on a stacked side surface of insulator layers to the semiconductor substrate and another electrode is on a lower surface of the semiconductor substrate. Therefore, in a case in which a substrate on which this semiconductor device is mounted is a conductor of ground potential, since the capacitor and the ground are electrically directly connected to each other, no wiring for connecting both is required. The capacitor of such a structure is referred to as a “vertical capacitor” for convenience in the present specification.
[Patent Literature 1] International Publication No. 98/012751
[Patent Literature 2] Japanese Unexamined Patent Application Publication No. 2021-93439

### BRIEF SUMMARY OF THE DISCLOSURE

In the high frequency integrated circuit device disclosed in Patent Literature 1, in a case in which a power amplifier for a communication device is configured, for example, the power amplifier may be placed on a copper-foil surface of the ground potential provided on a circuit board. In addition, such a high frequency integrated circuit device includes a capacitor inserted between a signal line and the ground. In a case in which this capacitor is configured with the MIM, it is necessary to connect one electrode of the capacitor to the ground with a wiring structure such as a wire. In such a case, a parasitic impedance due to the wiring structure is electrically inserted with between the capacitor and the ground, which is a factor in the deterioration of electrical characteristics such as a Q value of a capacitor.

In a case of the vertical capacitor as disclosed in Patent Literature 2, the problem of the deterioration of electrical circuit characteristics due to the wiring structure does not occur. However, as shown in Patent Literature 1, when, at the insulator layers stacked on the semiconductor substrate, a passive device such as an inductor (hereinafter, referred to as a “pattern inductor”) by a conductor pattern is provided and a vertical capacitor is provided, the electrical characteristics such as the Q value of the inductor deteriorate, as described below.

First, the equivalent series resistance (ESR) of the vertical capacitor will be considered. The equivalent series resistance of the vertical capacitor is determined by the conductivity of internal wiring or semiconductor substrate, which is a path of a current flowing through the capacitor. Generally, the semiconductor substrate has low conductivity and also has a longer current path than the internal wiring. Therefore, the conductivity of the semiconductor substrate tends to be a main factor that increases the equivalent series resistance of the vertical capacitor. In order to reduce the equivalent series resistance of the vertical capacitor, the conductivity of the semiconductor substrate needs to be increased.

In addition, the equivalent series resistance (ESR) of the pattern inductor is also determined by the conductivity of the conductor pattern including the internal wiring or the semiconductor substrate. In other words, since the conductor pattern is a portion of the current path of the inductor, the equivalent series resistance of the pattern inductor is directly affected by the conductivity of the conductor pattern.

However, as will be described herein, the mechanisms by which the conductivity of the semiconductor substrate causes the equivalent series resistance are different in the vertical capacitor and the pattern inductor. An object of the present disclosure is to provide an electronic component and a circuit device including an inductor with a high Q value and a capacitor with a high Q value, in a case in which, at insulator layers stacked on a semiconductor substrate, an inductor by a wiring pattern is provided and a vertical capacitor is provided.

The pattern inductor, when acting as an inductor, generates a high-frequency magnetic field around the pattern inductor, and this high-frequency magnetic field induces an eddy current in a conductor in the vicinity of the pattern inductor and this eddy current generates Joule heat. This Joule heat is generally called eddy current loss and is large as the conductivity of the conductor through which the eddy current flows is high. The eddy current loss appears as the equivalent series resistance in terms of the electrical characteristics of the inductor.

In the structure in which the pattern inductor is provided at the insulator layers stacked on the semiconductor substrate, the “semiconductor substrate” is the “conductor in the vicinity of the inductor.” Therefore, in order to reduce the equivalent series resistance of the pattern inductor, the conductivity of the semiconductor substrate needs to be reduced.

However, the equivalent series resistance of the vertical capacitor and the equivalent series resistance of the pattern inductor, since being affected by the conductivity of a silicon substrate, are in a trade-off relationship. For example, when the conductivity of the silicon substrate is increased in order to improve the Q value of the vertical capacitor, the Q value of the pattern inductor deteriorates, and, when the conductivity of the silicon substrate is reduced in order to improve the Q value of the pattern inductor, the Q value of the vertical capacitor deteriorates.

In view of the above, an electronic component as an example of the present disclosure includes: a semiconductor substrate having a first surface and a second surface; an insulator layer on the first surface of the semiconductor substrate; a plurality of conductor layers on and/or in the insulator layer; a dielectric layer on the first surface of the semiconductor substrate; a lower surface electrode on the second surface of the semiconductor substrate, wherein: at least a first conductor layer of the plurality of conductor layers is a wiring pattern, at least a second conductor layer of the plurality of conductor layers is a plate electrode that is paired with the semiconductor substrate or the lower surface electrode across the dielectric layer, and the semiconductor substrate has a first region that includes the dielectric layer and the plate electrode and a second region other than the first region; and a conductor portion with higher conductivity than the semiconductor substrate in the first region at a higher ratio than in the second region.

In addition, a circuit device as an example of the present disclosure includes the electronic component and a mounting substrate on which this electronic component is mounted, and the lower surface electrode of the electronic component is connected to a ground pattern of the mounting substrate.

According to the present disclosure, an electronic component including an inductor with a high Q value by a significant reduction of an eddy current flowing into a semiconductor substrate, and a capacitor with a high Q value by a reduction in equivalent series resistance is obtained.

### BRIEF DESCRIPTION OF THE DRAWINGS

FIG. 1A is a plan view of an electronic component 101 according to a first exemplary embodiment of the present disclosure, and FIG. 1B is a cross-sectional view taken along a line B-B in FIG. 1A.

FIG. 2 is a circuit diagram of the electronic component 101.

FIG. 3 is a block diagram showing a circuit configuration of a transmitter of a communication device.

FIG. 4A is a circuit diagram of a different electronic component 101A from the electronic component 101 shown in FIG. 1A and FIG. 1B, and FIG. 4B is a circuit diagram of another electronic component 101B different from the electronic component 101 shown in FIG. 1A and FIG. 1B.

FIG. 5 is a cross-sectional view of an electronic component 102 according to a second exemplary embodiment of the present disclosure.

FIG. 6 is a cross-sectional view of an electronic component 103 according to a third exemplary embodiment of the present disclosure.

FIG. 7 is a cross-sectional view of an electronic component 104 according to a fourth exemplary embodiment of the present disclosure.

FIG. 8 is a cross-sectional view of an electronic component 105 according to a fifth exemplary embodiment of the present disclosure.

FIG. 9A is a partial vertical cross-sectional view of an electronic component 106 according to a sixth exemplary embodiment of the present disclosure, and FIG. 9B is a plan cross-sectional view taken along a line X-X in FIG. 9A.

FIG. 10 is a partial plan cross-sectional view of an electronic component 107 according to a seventh exemplary embodiment of the present disclosure.

### DESCRIPTION OF EXEMPLARY EMBODIMENTS

Hereinafter, a plurality of exemplary embodiments of the present disclosure will be described with reference to the attached drawings and several specific examples. In the drawings, components and elements assigned with the same reference numerals or symbols will represent identical components and elements. While an exemplary embodiment of the present disclosure is divided and described into a plurality of exemplary aspects for the sake of convenience in consideration of ease of description or understanding of main points, elements described in different exemplary embodiments are able to be partially replaced or combined with each other. In the second and subsequent exemplary embodiments, a description of features common to the first exemplary embodiment will be omitted, and only different features will be described. In particular, the same advantageous functions and effects by the same configurations will not be described one by one for each exemplary embodiment.

### First Exemplary Embodiment

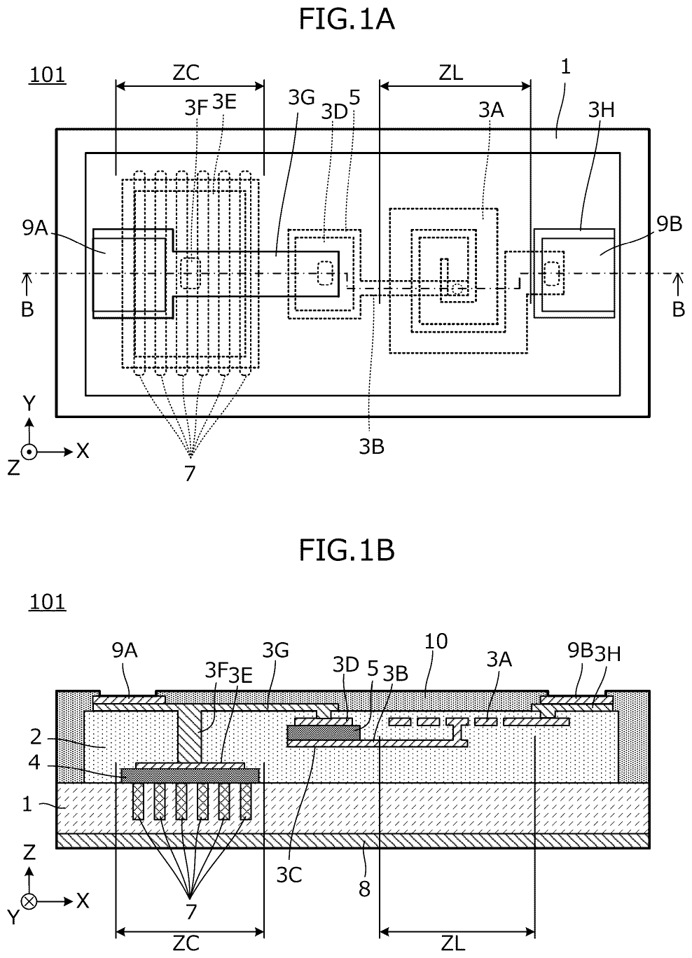

FIG. 1A is a plan view of an electronic component 101 according to the first exemplary embodiment of the present disclosure, and FIG. 1B is a cross-sectional view taken along a line B-B in FIG. 1A. However, FIG. 1A is a plan view of a state before a protective film 10 to be described below is provided.

This electronic component 101 includes a semiconductor substrate 1, an insulator layer 2 provided on the semiconductor substrate 1, conductor layers 3A, 3B, 3C, 3D, 3E, 3F, 3G, and 3H provided on or in the insulator layer 2, a dielectric layer 4 provided on the semiconductor substrate 1, a dielectric layer 5 provided in the insulator layer 2, a first pad electrode 9A and a second pad electrode 9B that are provided on the conductor layers 3G and 3H, a protective film 10 provided near an upper surface of the semiconductor substrate 1, and a lower surface electrode 8 provided on a lower surface of the semiconductor substrate 1.

As examples, the semiconductor substrate 1 is a substrate made of an impurity semiconductor such as a carrier doped silicon substrate, the insulator layer 2 is an SiN film, the conductor layers 3A, 3B, 3C, 3D, and 3E are Al films, the conductor layers 3F, 3G, and 3H are Cu films, the dielectric layers 4 and 5 are SiO₂ films, the first pad electrode 9A and the second pad electrode 9B are metal films of which the ground is Ni and the surface is Au, the protective film 10 is an organic insulating film such as solder resist, and the lower surface electrode 8 is a metal film of which the ground is Cu or Ni and the surface is Au.

A wiring pattern of the conductor layers 3A and 3B configures an inductor. The conductor layers 3C and 3D configure a capacitor electrode provided in the insulator layer 2. The conductor layer 3E configures a plate electrode on the dielectric layer 4. The conductor layers 3F, 3G, and 3H configure an extended electrode. The first pad electrode 9A and the second pad electrode 9B are used as, for example, a pad for wire bonding. The lower surface electrode 8 is used as, for example, an electrode for die bonding.

The wiring pattern of the conductor layers 3A and 3B provides an inductor region ZL in the semiconductor substrate 1. In addition, a region of the semiconductor substrate 1 in which the conductor layer 3E and the dielectric layer 4 as a plate electrode are provided is a capacitor region ZC. This capacitor region ZC is an example of a first region according to the present disclosure. A region of the semiconductor substrate 1 other than the first region is a second region.

A conductor portion 7 is provided in the capacitor region ZC of the semiconductor substrate 1. In this example, the conductor portion 7 is placed at a lower part of the dielectric layer 4. In the present exemplary embodiment, the inductor region ZL is a portion of the second region. The conductor portion 7 is placed in the capacitor region ZC (the first region) in the semiconductor substrate 1 at a higher ratio than in the second region of the semiconductor substrate 1 including the inductor region ZL. The conductor portion 7 is made of, for example, conductive polysilicon and has higher conductivity than the semiconductor substrate 1. This conductor portion 7 is provided by digging a plurality of trenches, for example, in the semiconductor substrate 1 and filling the conductive polysilicon or the like in these trenches.

In the present exemplary embodiment, the conductor layer 3E is configured by a side extending in an X-axis direction and a side extending in a Y-axis direction, and a plurality of conductor portions 7 extend in parallel to each other in the Y-axis direction.

The conductor layers 3A and 3B are spiral shaped conductor layers and configure an inductor. The conductor layer 3E, the dielectric layer 4, the semiconductor substrate 1, the conductor portion 7, and the lower surface electrode 8 configure a capacitor. Herein, the conductor layer 3E is a first electrode of the capacitor, and the semiconductor substrate 1, the conductor portion 7, and the lower surface electrode 8 are second electrodes of the capacitor.

As shown above, the conductor portion 7 with higher conductivity than the semiconductor substrate 1 is placed in the capacitor region ZC in the semiconductor substrate 1 at a higher ratio than in the inductor region ZL. Accordingly, the conductivity of the semiconductor substrate 1 is able to be reduced, so that an eddy current induced in the semiconductor substrate 1 by the high-frequency magnetic field that the wiring pattern by the conductor layers 3A and 3B generates is significantly reduced, and thus an inductor with a high Q value is obtained. In addition, the conductivity of the capacitor region ZC in which the conductor layer 3E as a plate electrode is provided is able to be increased, and a capacitor with a high Q value is obtained.

The electronic component 101 shown above is mounted on a mounting substrate for mounting the electronic component. This mounting substrate and the electronic component 101 configure a circuit device. A ground pattern and other electrode patterns are provided on the mounting substrate. The first pad electrode 9A is electrically connected to the conductor layer 3E, the second pad electrode 9B is electrically connected to one end of the conductor layer 3A that provides an inductor pattern, and the other end of the conductor layer 3A and the conductor layer 3E are electrically connected to each other.

The lower surface electrode 8 of the electronic component 101 is connected to the ground pattern provided on the mounting substrate, and the first pad electrode 9A and the second pad electrode 9B are wire-bonded to electrode patterns other than the ground pattern provided on the mounting substrate.

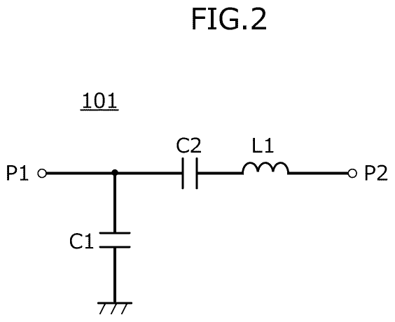

FIG. 2 is a circuit diagram of the electronic component 101. Ports P1 and P2 shown in FIG. 2 correspond to the first pad electrode 9A and the second pad electrode 9B of the electronic component 101 that are shown in FIG. 1A and FIG. 1B, respectively, and the ground shown in FIG. 2 corresponds to the lower surface electrode 8 in FIG. 1A and FIG. 1B. A capacitor C1 shown in FIG. 2 is a capacitor configured by the conductor layer 3E, the dielectric layer 4, the conductor portion 7, the semiconductor substrate 1, and the lower surface electrode 8. A capacitor C2 shown in FIG. 2 is a capacitor configured by the conductor layers 3C and 3D and the dielectric layer 5. An inductor L1 shown in FIG. 2 is an inductor configured by the conductor layers 3A and 3B. Such an LC circuit configures an impedance matching circuit.

The capacitor C1 provided in the capacitor region ZC is connected to the ground pattern of the mounting substrate through the semiconductor substrate 1 or the conductor portion, so that the equivalent series resistance ESR is able to be significantly reduced in comparison with a path device of the structure through wiring, and thus an impedance matching circuit with a high Q value is obtained.

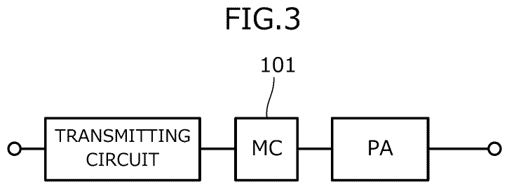

FIG. 3 is a block diagram showing a circuit configuration of a transmitter of a communication device. This transmitter includes a transmitting circuit that receives a transmission signal and modulates the transmission signal to output a high-frequency transmission signal, a power amplifier PA, and an impedance matching circuit MC that performs impedance matching between the transmitting circuit and the power amplifier PA. A signal outputted from the power amplifier PA is led to an antenna. The communication device including the transmitter shown in this FIG. 3 is provided, for example, in a base station.

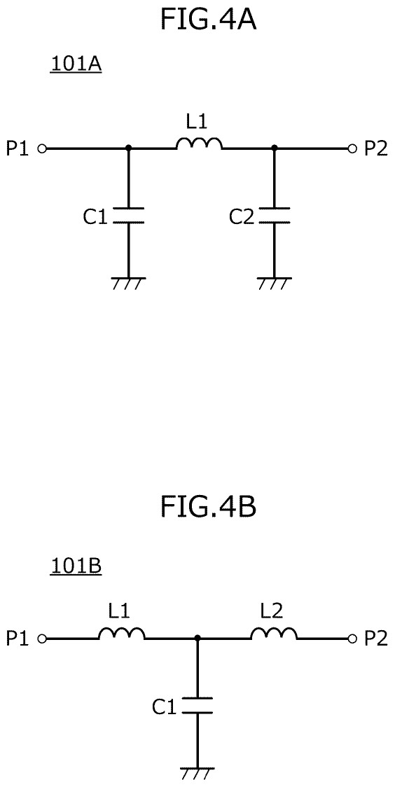

FIG. 4A is a circuit diagram of a different electronic component 101A from the electronic component 101 shown in FIG. 1A and FIG. 1B, and FIG. 4B is a circuit diagram of another electronic component 101B different from the electronic component 101 shown in FIG. 1A and FIG. 1B. The electronic component 101A is a π-type impedance matching circuit by the capacitors C1 and C2 and the inductor L1, and the electronic component 101B is a T-type impedance matching circuit by the inductors L1 and L2 and the capacitor C1.

In the electronic component 101A, the capacitors C1 and C2 to be shunt-connected between a signal line and a ground are vertical capacitors configured in the capacitor region ZC in FIG. 1A and FIG. 1B. In addition, the inductor L1 inserted in series in the signal line is an inductor configured in the inductor region ZL in FIG. 1A and FIG. 1B.

In the electronic component 101B, the capacitor C1 to be shunt-connected between the signal line and the ground is a vertical capacitor configured in the capacitor region ZC in FIG. 1A and FIG. 1B. In addition, the inductors L1 and L2 inserted in series in the signal line are inductors configured in the inductor region ZL in FIG. 1A and FIG. 1B.

In this manner, an impedance matching circuit configured by a capacitor with a high Q value and an inductor with a high Q value is obtained.

It is to be noted that, while the example shown in FIG. 1A, FIG. 1B, and FIG. 2 shows an example in which the lower surface electrode 8 provided on the lower surface of the semiconductor substrate 1 is connected to the ground of the impedance matching circuit for the purpose of reducing the ESR in the capacitor C1 shunt-connected between the signal line and the ground, the use of the first pad electrode 9A and the lower surface electrode 8 is not limited to this example. For example, the first pad electrode 9A may be connected to a circuit ground, and the lower surface electrode 8 may be used as a port of the signal line. In other words, the lower surface electrode of the semiconductor substrate 1 may be used as the capacitor electrode.

### Second Exemplary Embodiment

In a second exemplary embodiment, an electronic component different in the configuration of the conductor portion provided in the capacitor region from the example shown in the first exemplary embodiment will be described.

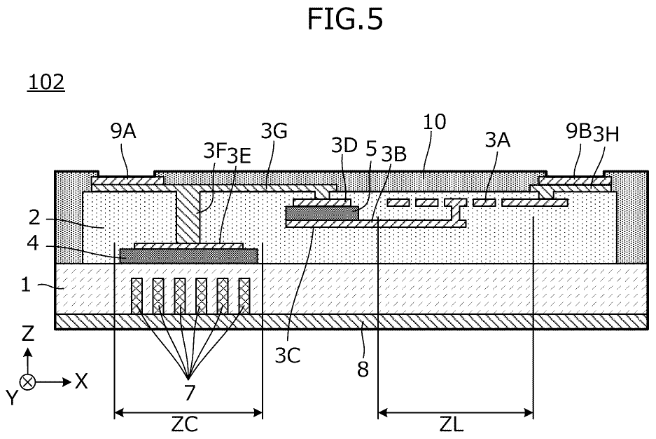

FIG. 5 is a cross-sectional view of an electronic component 102 according to the second exemplary embodiment of the present disclosure. The cross-sectional positions correspond to the positions shown in FIG. 1B. While the conductor portions 7 are provided at an upper part of the semiconductor substrate 1 in the electronic component 101 shown in FIG. 1B, the conductor portions 7 in the example shown in FIG. 5 are provided at a lower part of the semiconductor substrate 1. In addition, the conductor portions 7 are directly conducted, that is, contacted to the lower surface electrode 8. In other words, while, in the example of the electronic component 101 shown in FIG. 1B, the conductor portions 7 are provided by digging a plurality of trenches in the upper part of the semiconductor substrate 1 and embedding a conductor in these trenches, in the example shown in FIG. 5, the conductor portions 7 are provided by digging a plurality of trenches in the lower part of the semiconductor substrate 1 and embedding the conductor in these trenches.

As shown in the present exemplary embodiment, the conductor portions 7 to be placed in the capacitor region ZC may be provided at the lower part of the semiconductor substrate 1. In the electronic component 102 as well, the composite conductivity of the semiconductor substrate 1, the conductor portion 7, and the lower surface electrode 8 that configure the second electrodes of the vertical capacitor is high, so that a capacitor with a high Q value is able to be configured.

### Third Exemplary Embodiment

In a third exemplary embodiment, an electronic component different in the configuration of the conductor portion provided in the capacitor region from the example shown in each of the above exemplary embodiments will be described.

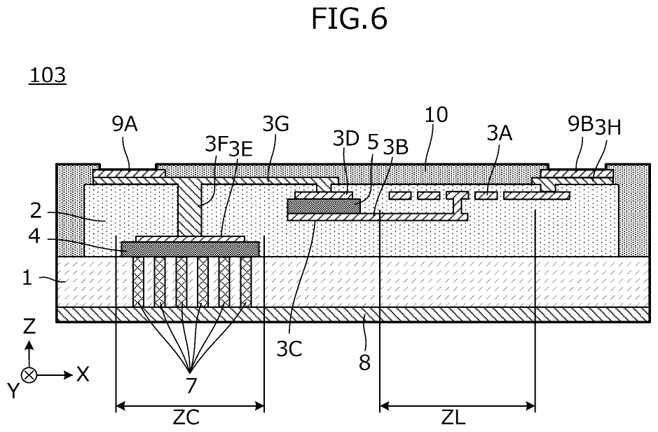

FIG. 6 is a cross-sectional view of an electronic component 103 according to the third exemplary embodiment of the present disclosure. The cross-sectional positions correspond to the positions shown in FIG. 1B. While the conductor portions 7 are provided at positions near the upper part of the semiconductor substrate 1 in the electronic component 101 shown in FIG. 1B, the conductor portions 7 in the example shown in FIG. 6 are provided from the upper surface to the lower surface of the semiconductor substrate 1.

As shown in the present exemplary embodiment, the conductor portions 7 to be placed in the capacitor region ZC may be provided from the upper surface to the lower surface of the semiconductor substrate 1. In the electronic component 103 as well, the composite conductivity of the semiconductor substrate 1, the conductor portion 7, and the lower surface electrode 8 that configure the second electrodes of the vertical capacitor is high, so that a capacitor with a high Q value is able to be configured.

### Fourth Exemplary Embodiment

In a fourth exemplary embodiment, an electronic component different in the configuration of the conductor portion provided in the capacitor region from the example shown in each of the above exemplary embodiments will be described.

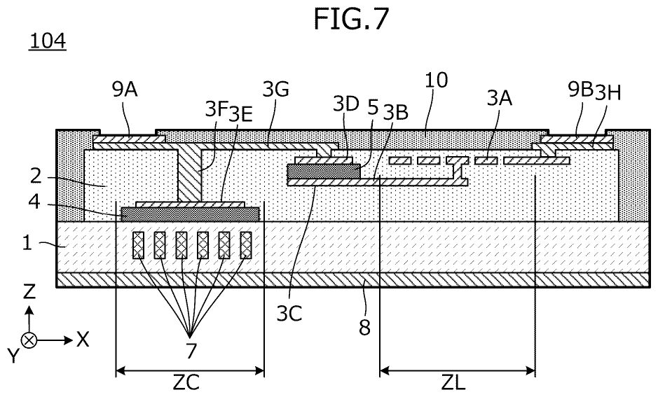

FIG. 7 is a cross-sectional view of an electronic component 104 according to the fourth exemplary embodiment of the present disclosure. The cross-sectional positions correspond to the positions shown in FIG. 1B. While the conductor portions 7 are provided at a position near the upper part of the semiconductor substrate 1 in the electronic component 101 shown in FIG. 1B, the conductor portions 7 in the example shown in FIG. 7 are provided inside the semiconductor substrate 1.

As shown in the present exemplary embodiment, the conductor portions 7 to be placed in the capacitor region ZC may be provided inside the semiconductor substrate 1. In the electronic component 104 as well, the composite conductivity of the semiconductor substrate 1, the conductor portion 7, and the lower surface electrode 8 that configure the second electrodes of the vertical capacitor is high, so that a capacitor with a high Q value is able to be configured.

### Fifth Exemplary Embodiment

In a fifth exemplary embodiment, an electronic component different in the configuration of the conductor portion provided in the capacitor region from the example shown in each of the above exemplary embodiments will be described.

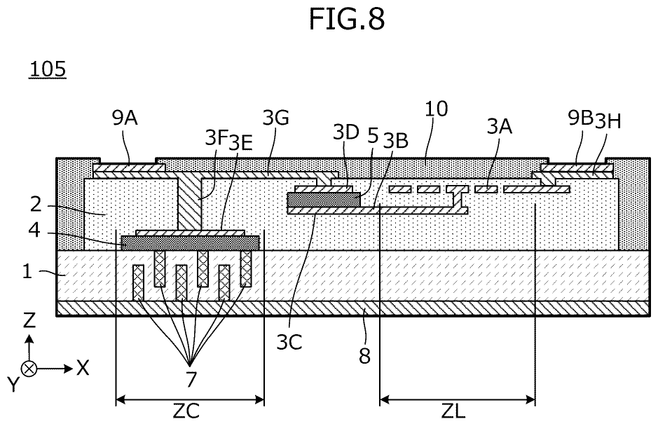

FIG. 8 is a cross-sectional view of an electronic component 105 according to the fifth exemplary embodiment of the present disclosure. The cross-sectional positions correspond to the positions shown in FIG. 1B. While the conductor portions 7 are provided at the upper part of the semiconductor substrate 1 in the electronic component 101 shown in FIG. 1B, and the conductor portions 7 in the electronic component 102 shown in FIG. 5 are provided at the lower part of the semiconductor substrate 1, in the example shown in FIG. 8, some of the plurality of conductor portions 7 are provided at the upper part of the semiconductor substrate 1 and others of the plurality of conductor portions 7 are provided at the lower part of the semiconductor substrate 1.

As shown in the present exemplary embodiment, the conductor portions 7 to be placed in the capacitor region ZC may be provided at both the upper part and the lower part of the semiconductor substrate 1. In the electronic component 102 as well, the composite conductivity of the semiconductor substrate 1, the conductor portion 7, and the lower surface electrode 8 that configure the second electrodes of the vertical capacitor is high, so that a capacitor with a high Q value is able to be configured.

### Sixth Exemplary Embodiment

In a sixth exemplary embodiment, an electronic component different in the configuration of the vertical capacitor from the example shown in each of the above exemplary embodiments will be described.

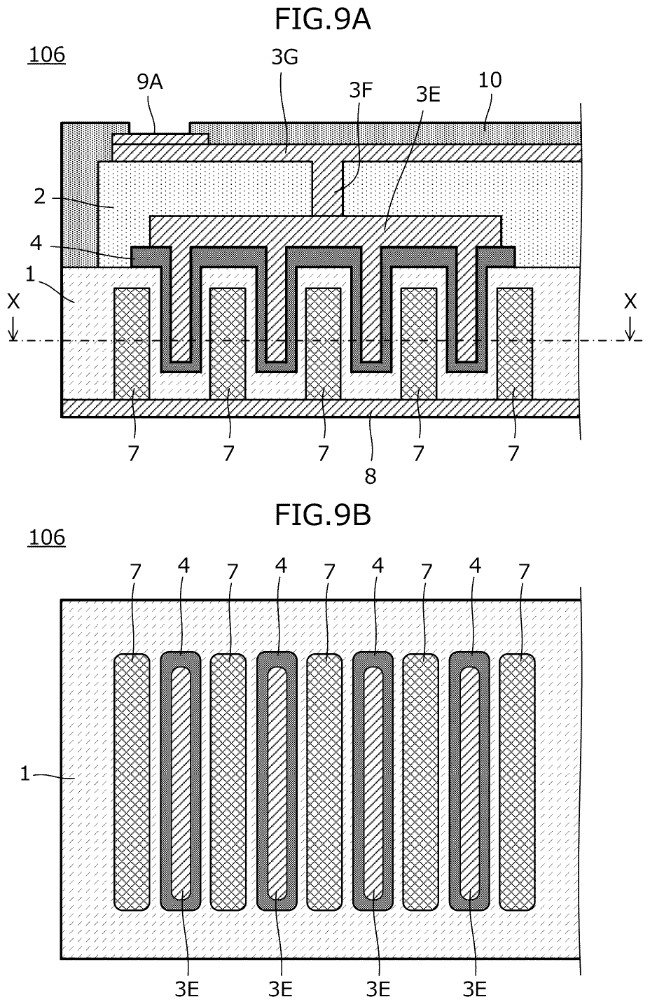

FIG. 9A is a partial vertical cross-sectional view of an electronic component 106 according to the sixth exemplary embodiment of the present disclosure, and FIG. 9B is a plan cross-sectional view taken along a line X-X in FIG. 9A. Both FIG. 9A and FIG. 9B illustrate a portion of the vertical capacitor and the configuration of other portions is the same as the configuration of the electronic component shown in the above exemplary embodiments.

The electronic component 106 according to the present exemplary embodiment includes a semiconductor substrate 1, an insulator layer 2 provided on the semiconductor substrate 1, conductor layers 3E, 3F, and 3G provided at the insulator layer 2, a dielectric layer 4 provided on the semiconductor substrate 1, a first pad electrode 9A provided on the conductor layer 3G, a protective film 10 provided near an upper surface of the semiconductor substrate 1, and a lower surface electrode 8 provided on a lower surface of the semiconductor substrate 1. Examples of the material of each portion are as described in the first exemplary embodiment.

In the present exemplary embodiment, the dielectric layer 4 is provided by digging a plurality of trenches in the upper surface of the semiconductor substrate 1 and coating an inner surface of the trenches and the upper surface of the semiconductor substrate 1 with a dielectric material. In addition, the conductor layer 3E coats the dielectric layer 4. The conductor portions 7 are provided by digging a plurality of trenches in the lower surface of the semiconductor substrate 1 and embedding the conductor in these trenches.

According to the present exemplary embodiment, a space between the conductor portions 7 and the dielectric layer 4 is able to be reduced, so that the Q value of the vertical capacitor is able to be effectively increased. In addition, an effective area of the dielectric layer 4 between the conductor layer 3E and the semiconductor substrate 1 is able to be increased, and the vertical capacitor is able to be reduced in size.

### Seventh Exemplary Embodiment

In a seventh exemplary embodiment, an electronic component different in the configuration of the vertical capacitor from the example shown in each of the above exemplary embodiments will be described.

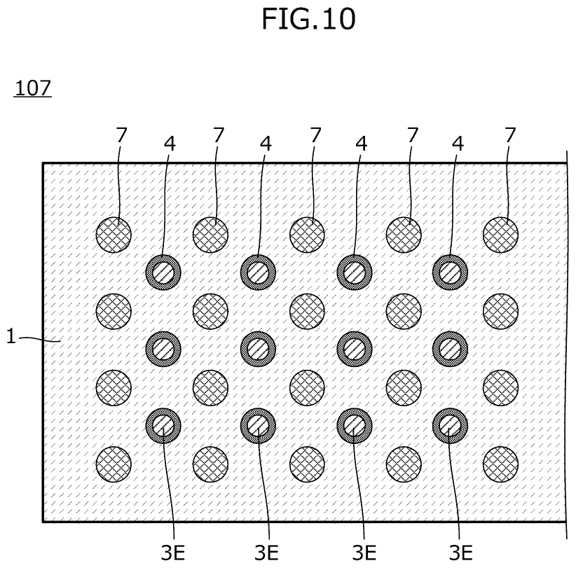

FIG. 10 is a partial plan cross-sectional view of an electronic component 107 according to the seventh exemplary embodiment of the present disclosure. The cross-sectional positions correspond to the positions shown in FIG. 9B.

While, in the example shown in FIG. 9A and FIG. 9B, the lower part of the conductor layer 3E and the conductor portions 7 are provided in a linear shape and the lower part of the dielectric layer 4 is provided in a trench shape, in the present exemplary embodiment, the conductor layer 3E and the lower part of the conductor portions 7 are provided in a cylindrical shape and the lower part of the dielectric layer 4 is provided in a tubular shape.

According to the present exemplary embodiment, similarly to the sixth exemplary embodiment, a space between the conductor portions 7 and the dielectric layer 4 is able to be reduced, so that the Q value of the vertical capacitor is able to be effectively increased. In addition, an effective area of the dielectric layer 4 between the conductor layer 3E and the semiconductor substrate 1 is able to be increased, and the vertical capacitor is able to be reduced in size.

In each exemplary embodiment shown above, the inductor pattern to be provided in the inductor region ZL, while having a spiral shape, is not limited to the spiral shape. The inductor pattern to be provided in the inductor region ZL, for example, may have a loop shape or may have a helical shape configured by stacking a plurality of loop shaped conductor patterns and connecting the conductor patterns with interlayer connection conductors.

Moreover, while FIG. 1A and FIG. 1B show the conductor portions extended in the Y-axis direction, the shape of the conductor portions is not limited to this example. The conductor portions, for example, may have a plurality of cylindrical shapes, may have a plurality of cross shapes, or may have a plurality of tubular shapes.

Finally, the present disclosure is not limited to the foregoing exemplary embodiments. Various modifications or changes can be appropriately made by those skilled in the art. The scope of the present disclosure is defined not by the foregoing exemplary embodiments but by the following claims. Furthermore, the scope of the present disclosure is intended to include all possible modifications or changes from the exemplary embodiments within the scopes of the claims and the scopes of equivalents.

While each exemplary embodiment shows the electronic component including a capacitor and an inductor as a passive component, the present disclosure is also applicable to an electronic component including an active component as well as a passive component.

In addition, in the example shown in FIG. 1A and FIG. 1B, when viewed in a direction perpendicular to a plane of the semiconductor substrate 1, the conductor portions 7, while fitting in the region in which the dielectric layer 4 is provided in the X-axis direction and protruding from the region in which the dielectric layer 4 is provided in the Y-axis direction, are not limited to this example. For example, the conductor portions 7 may be also placed outside the region in which the dielectric layer 4 is provided in the X-axis direction. In such a case as well, it is useful to increase the substantial conductivity of the current path through the second electrodes configured by the semiconductor substrate 1, the conductor portion 7, and the lower surface electrode 8.

Moreover, in each of the plurality of exemplary embodiments shown above, the conductor portions 7, while being placed only in the capacitor region ZC of the vertical capacitor, may be placed outside the capacitor region. In such a case as well, the conductor portions 7 may be placed in the capacitor region ZC in the semiconductor substrate 1 at a higher ratio than in the inductor region ZL.

### REFERENCE SIGNS LIST

C1, C2—capacitor
L1, L2—inductor
MC—impedance matching circuit
P1, P2—port
PA—power amplifier
ZC—capacitor region
ZL—inductor region
1—semiconductor substrate
2—insulator layer
3A, 3B, 3C, 3D, 3E, 3F, 3G, 3H—conductor layer
4, 5—dielectric layer
7—conductor portion
8—lower surface electrode
9A—first pad electrode
9B—second pad electrode
10—protective film
101, 101A, 101B, 102, 103, 104, 105, 106, 107—electronic component

1. An electronic component comprising:
a semiconductor substrate having a first surface and a second surface;
an insulator layer on the first surface of the semiconductor substrate;
a plurality of conductor layers on and/or in the insulator layer;
a dielectric layer on the first surface of the semiconductor substrate;
a lower surface electrode on the second surface of the semiconductor substrate,
wherein:
at least a first conductor layer of the plurality of conductor layers is a wiring pattern,
at least a second conductor layer of the plurality of conductor layers is a plate electrode that is paired with the semiconductor substrate or the lower surface electrode across the dielectric layer, and
the semiconductor substrate has a first region that includes the dielectric layer and the plate electrode and a second region other than the first region; and
a conductor portion with higher conductivity than the semiconductor substrate in the first region at a higher ratio than in the second region.

2. The electronic component according to claim 1, wherein the conductor portion is in a region of the semiconductor substrate having the dielectric layer.

3. The electronic component according to claim 2, wherein the conductor portion is embedded in the semiconductor substrate and includes a plurality of conductor portions.

4. The electronic component according to claim 3, wherein the plurality of conductor portions are in contact with the dielectric layer.

5. The electronic component according to claim 3, wherein the plurality of conductor portions are in contact with the lower surface electrode.

6. The electronic component according to claim 3, wherein the plurality of conductor portions are in contact with the dielectric layer and the lower surface electrode.

7. The electronic component according to claim 3, wherein the plurality of conductor portions are inside the semiconductor substrate.

8. The electronic component according to claim 3, wherein a first set of the plurality of conductor portions are in contact with the dielectric layer, and a second set of the plurality of conductor portions are in contact with the lower surface electrode.

9. The electronic component according to claim 1, wherein the first surface of the semiconductor substrate includes a first plurality of trenches, the second surface of the semiconductor substrate includes a second plurality of trenches, the dielectric layer is on an inner surface of the first plurality of trenches, and the conductor portion is in the second plurality of trenches.

10. The electronic component according to claim 9, wherein the first plurality of trenches and the second plurality of trenches are linear.

11. The electronic component according to claim 9, wherein the first plurality of trenches and the second plurality of trenches are cylindrical.

12. The electronic component according to claim 1, wherein:
at least a third conductor layer of the plurality of conductor layers is an inductor pattern of a spiral shape or a loop shape;
the inductor pattern is in the second region of the semiconductor substrate; and
the conductor portion is not in an inductor region of the semiconductor substrate having the inductor pattern.

13. The electronic component according to claim 12, wherein:
portions of the plurality of conductor layers configure a first pad electrode and a second pad electrode, respectively;
the first pad electrode is electrically connected to the plate electrode;
the second pad electrode is electrically connected to a first end of the inductor pattern; and
the plate electrode is electrically connected to a second end of the inductor pattern.

14. The electronic component according to claim 1, wherein the conductor portion is in contact with the dielectric layer.

15. The electronic component according to claim 1, wherein the conductor portion is in contact with the lower surface electrode.

16. The electronic component according to claim 1, wherein the conductor portion is in contact with the dielectric layer and the lower surface electrode.

17. The electronic component according to claim 1, wherein the conductor portion is inside the semiconductor substrate.

18. The electronic component according to claim 1, wherein the conductor portion includes a first set of conductor portions in contact with the dielectric layer, and a second set of conductor portions in contact with the lower surface electrode.

19. A circuit device comprising:
a mounting substrate having a ground pattern; and
the electronic component according to claim 1 mounted on the mounting substrate such that the lower surface electrode of the electronic component is connected to the ground pattern of the mounting substrate.
